(19) United States
(12) Patent Application Publication
(10) Pub. No.: US 2026/0205104 A1
(43) Pub. Date: Jul. 16, 2026

(54) HIGHLY COMPATIBLE POWER CONTROLLER

(71) Applicant: Xiamen PVTECH Co., Ltd., Xiamen (CN)

(72) Inventors: Rongtu LIU, Xiamen (CN); Fuxing LU, Xiamen (CN); Chunming LIU, Xiamen (CN)

(21) Appl. No.: 19/567,147

(22) Filed: Mar. 15, 2026

Related U.S. Application Data
(63) Continuation-in-part of application No. 19/012,882, filed on Jan. 8, 2025.

(51) Int. Cl. H03K 17/0812; H03K 17/08; H05B 45/37; H05B 45/56

(52) U.S. Cl. CPC H03K 17/08122; H03K 2017/0806; H05B 45/37; H05B 45/56

(57) ABSTRACT

A power controller includes a signal identification element including a low-frequency signal identifier, a switch driver, a switch element. The low-frequency signal identifier includes a comparator, a rising-edge trigger, a falling-edge trigger, a counting unit, and a latch. The comparator receives a second input signal and compares the second input signal with a first reference voltage to generate a comparison signal. The rising-edge trigger and the falling-edge trigger receive the comparison signal. The counting unit includes a counting element and an OR gate. The OR gate generates a logic signal according to the outputs of the rising-edge trigger and the falling-edge trigger, and the counting element generates a count output signal accordingly. The latch determines whether the second input signal is a direct-current signal or a power-frequency signal according to the logic signal and the count output signal l, thereby controlling the switch driver to operate the switch element.

### TECHNICAL FIELD

The present invention relates to a controller, in particular to a highly compatible power controller

### BACKGROUND

Lighting devices having emergency lighting functionality have become an important development trend. In particular, lighting products used in public places such as offices and libraries are generally equipped with an emergency power supply. The emergency power supply is typically provided in the form of a direct current voltage, with a voltage level generally higher than 80 V. In contrast, a power supply in a normal operating mode is the utility power (AC). Accordingly, a power controller must be capable of accurately determining whether an input power source is the utility power (AC) or an emergency power supply (DC), and of adopting corresponding driving strategies and control mechanisms, so as to ensure that the lighting device operates stably and with high efficiency.

However, currently available lighting devices require additional detection circuits, such as voltage comparison circuits formed of discrete components. Such circuits are susceptible to temperature drift and component aging, and prolonged operation may cause a shift in a comparison threshold, thereby resulting in misidentification of a power source type. Such designs not only increase hardware cost and circuit complexity, but may also adversely affect the accuracy and real-time performance of the determination result.

In addition, some currently available lighting devices distinguish power source types by analyzing waveform characteristics of an input voltage. However, such methods typically require high-precision sampling circuits and complex signal processing and comparison algorithms, thereby imposing relatively high demands on hardware resources. Moreover, during instantaneous power source switching, response delay is likely to occur.

### SUMMARY

One embodiment of the present invention provides a highly compatible power controller, which includes a signal identification element, a switch driver, a switch element. The signal identification element includes a low-frequency signal identifier. The low-frequency signal identifier includes a comparator, a rising-edge trigger, a falling-edge trigger, a counting unit, and a latch. The comparator receives a second input signal and to compare the second input signal with a first reference voltage to generate a comparison signal. The rising-edge trigger and the falling-edge trigger receive the comparison signal. The counting unit includes a counting element and an OR gate. The OR gate generates a logic signal according to the outputs of the rising-edge trigger and the falling-edge trigger, and the counting element generates a count output signal according to the logic signal. The latch determines whether the second input signal is a direct-current signal or a power-frequency signal according to the logic signal and the count output signal so as to control the switch driver to control the switch element.

As set forth above, the low-frequency signal identifier of the power controller adopts a simple logic determination circuit based on a counting mechanism, which does not require a voltage comparison circuit formed of discrete components. Accordingly, the low-frequency signal identifier is not readily affected by temperature drift or component aging, while still achieving accurate determination results. Therefore, the power controller can satisfy actual requirements.

Further scope of applicability of the present application will become more apparent from the detailed description given hereinafter. However, it should be understood that the detailed description and specific examples, while indicating exemplary embodiments of the present invention, are given by way of illustration only, since various changes and modifications within the spirit and scope of the present invention will become apparent to those skilled in the art from this detailed description.

### BRIEF DESCRIPTION OF DRAWINGS

The present invention will become more fully understood from the detailed description given herein below and the accompanying drawings which are given by way of illustration only, and thus are not limitative of the present invention and wherein:

FIG. 1 is the block diagram of the circuit structure of the highly compatible power controller in accordance with the first embodiment of the present invention.

FIG. 2 is the block diagram of the circuit structure of the high-frequency signal identifier of the highly compatible power controller in accordance with the first embodiment of the present invention.

FIG. 3 is the block diagram of the circuit structure of the highly compatible power controller in accordance with the second embodiment of the present invention.

FIG. 4 is the block diagram of the circuit structure of the highly compatible power controller in accordance with the third embodiment of the present invention.

FIG. 5 is the block diagram of the circuit structure of the highly compatible power controller in accordance with the fourth embodiment of the present invention.

FIG. 6 is the block diagram of the circuit structure of the highly compatible power controller in accordance with the fifth embodiment of the present invention.

FIG. 7 is the block diagram of the circuit structure of the highly compatible power controller in accordance with the sixth embodiment of the present invention.

FIG. 8 is the circuit diagram of the lighting device driver having the power controller in accordance with the sixth embodiment of the present invention.

FIG. 9 is the schematic view of the utility power mode of the lighting device driver having the power controller in accordance with the sixth embodiment of the present invention.

FIG. 10 is the schematic view of the ballast mode of the lighting device driver having the power controller in accordance with the sixth embodiment of the present invention.

FIG. 11 is the block diagram of the circuit structure of the highly compatible power controller in accordance with the seventh embodiment of the present invention.

FIG. 12 is the circuit diagram the low-frequency signal identifier of the highly compatible power controller in accordance with the seventh embodiment of the present invention.

FIG. 13 is the schematic view illustrating the operating state of the low-frequency signal identifier of the highly compatible power controller in accordance with the seventh embodiment of the present invention.

FIG. 14 is the block diagram of the circuit structure of the highly compatible power controller in accordance with the eighth embodiment of the present invention.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing. It should be understood that, when it is described that an element is “coupled” or “connected” to another element, the element may be “directly coupled” or “directly connected” to the other element or “coupled” or “connected” to the other element through a third element. In contrast, it should be understood that, when it is described that an element is “directly coupled” or “directly connected” to another element, there are no intervening elements.

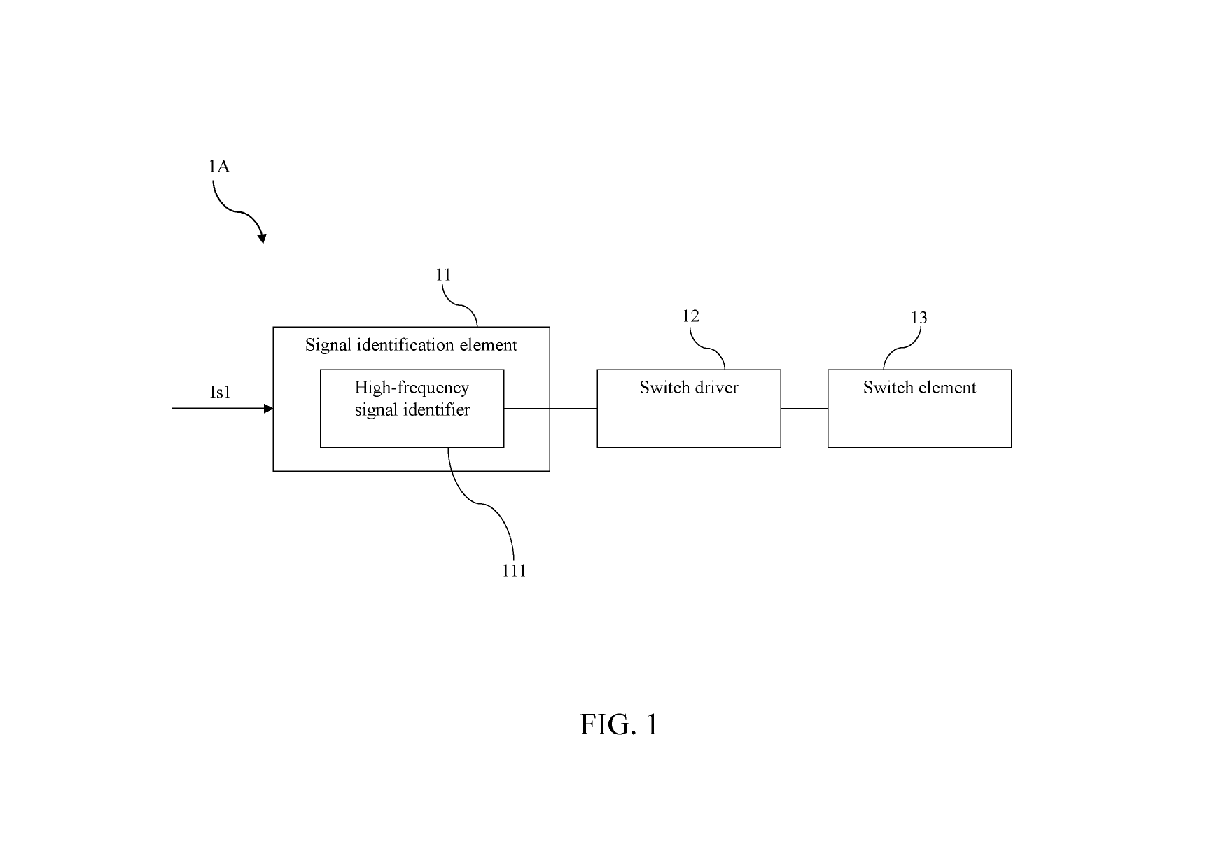

Please refer to FIG. 1, which is the block diagram of the circuit structure of the highly compatible power controller in accordance with the first embodiment of the present invention. As shown in FIG. 1, the power controller 1A includes a signal identification element 11, a switch driver 12, and a switch element 13.

The signal identification element 11 includes a high-frequency signal identifier 111. The high-frequency signal identifier 111 receives the first input signal Is1.

The switch driver 12 is connected to the high-frequency signal identifier 111. In this embodiment, the switch driver 12 may be a gate driver. In another embodiment, the switch driver 12 may be a signal amplifier or other components with signal amplification capabilities.

The switch element 13 is connected to the switch driver 12. In this embodiment, the switch element 13 may be a metal-oxide-semiconductor field-effect transistor (MOSFET). In another embodiment, the switch element 13 may also be a bipolar junction transistor (BJT) or other similar components.

The high-frequency signal identifier 111 executes a counting process within a preset time interval, which includes a preset number of counting cycles, to detect the number of sine waves in the first input signal Is1. The high-frequency signal identifier 111 generates a conduction signal when the number of sine waves in any counting cycle is greater than or equal to a preset threshold. The switch driver 12 activates the switch element 13 according to the conduction signal. The high-frequency signal identifier 111 then enters a deadlock state to stop the counting process.

Conversely, when the number of sine waves in each counting cycle is less than the preset threshold, the high-frequency signal identifier 111 enters a deadlock state, stopping the counting process.

Via the above counting mechanism and the specialized decision logic, the power controller 1 can effectively determine whether the first input signal Is1 is a signal from the ballast GH. When the number of sine waves in any counting cycle is greater than or equal to the preset threshold, the power controller 1 determines that the first input signal Is1 is a signal from the ballast GH, generates a conduction signal to activate the switch element 13, and outputs a direct-current signal. In this case, the power controller 1 operates in the ballast mode. The conduction signal mentioned above may be a direct-current signal, keeping the switch element 13 in the on state.

Conversely, when the number of sine waves in each counting cycle is less than the preset threshold, and the switch driver 12 activates the switch element 13 according to the conduction signal, the power controller 1 determines that the first input signal Is1 is noise. This noise may result from poor external switch contact or other factors. At this point, the high-frequency signal identifier 111 enters a deadlock state without generating a conduction signal to prevent the power controller 1 from malfunctioning.

The embodiment just exemplifies the present invention and is not intended to limit the scope of the present invention; any equivalent modification and variation according to the spirit of the present invention is to be also included within the scope of the following claims and their equivalents.

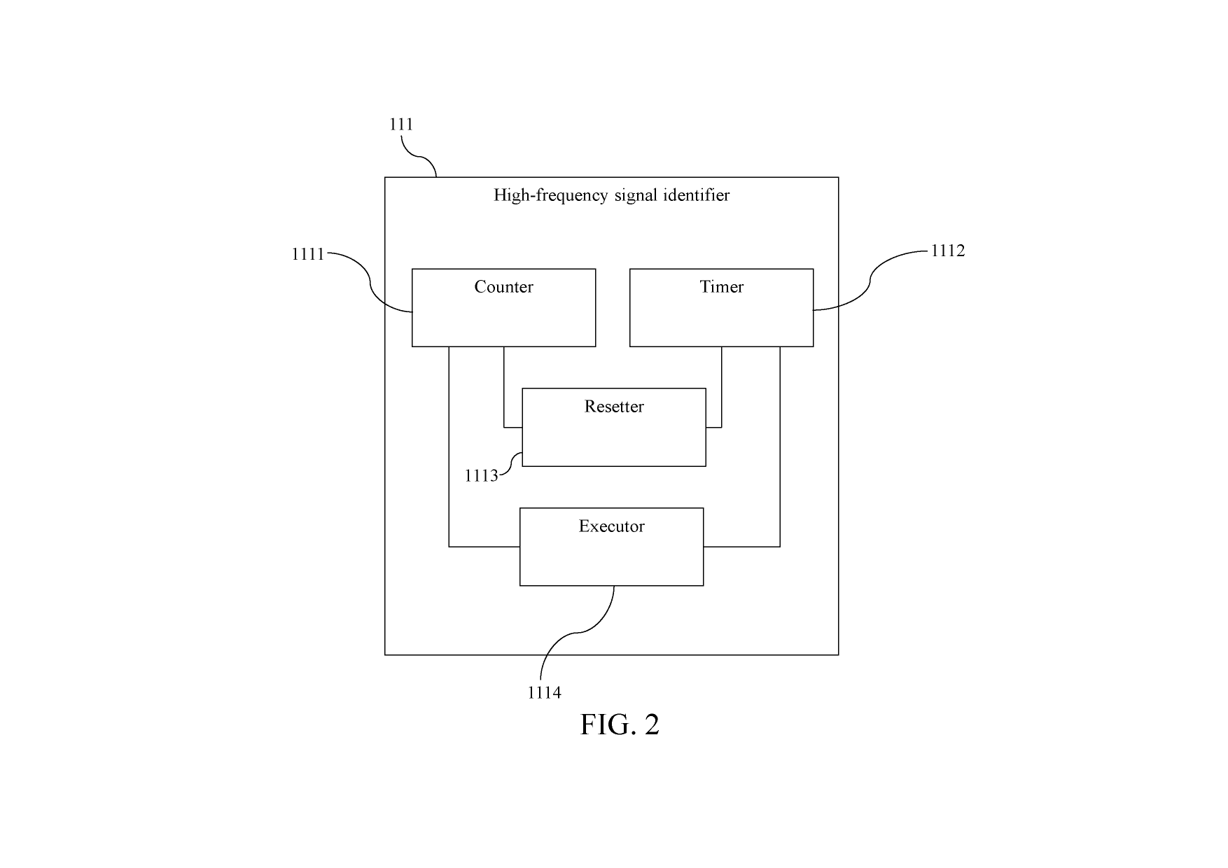

Please refer to FIG. 2, which is the block diagram of the circuit structure of the high-frequency signal identifier of the highly compatible power controller in accordance with the first embodiment of the present invention. As shown in FIG. 2, the high-frequency signal identifier 111 includes a counter 1111, a timer 1112, a resetter 1113, and an executor 1114.

The resetter 1113 is connected to the counter 1111 and the timer 1112. The counter 1111 and the timer 1112 are common integrated circuits and can be implemented using any existing circuit design, so no further details are provided here. The resetter 1113 may be a circuit with one or more of a resistor, a capacitor, or a diode.

The executor 1114 is connected to the counter 1111 and the timer 1112. The executor 1114 may be a circuit with one or more of a resistor, a capacitor, or a diode.

As mentioned earlier, the high-frequency signal identifier 111 can execute the counting process within a preset time interval. The counting process includes a preset number of counting cycles. When the high-frequency signal identifier 111 receives the first input signal Is1, the timer 1112 controls the executor 1114 to generate an execution signal to control the counter 1111 to execute the counting process and calculate the number of sine waves in the first input signal Is1. It also determines whether the number of sine waves in each counting cycle is greater than or equal to the preset threshold. The timer 1112 controls the duration of each counting cycle and, at the end of each cycle, controls the resetter 1113 to generate a reset signal to reset the counter 1111 for the next counting cycle.

For example, if the frequency threshold of the high-frequency signal identifier 111 is 20 kHz, and the frequency is not lower than 20 kHz, the high-frequency signal identifier 111 outputs a conduction signal to the switch driver 12, enabling the switch driver 12 to activate the switch element 13 based on the conduction signal. In this case, the sine wave period of the single high-frequency signal is 50 µs. The timer 1112 sets the counting cycle to 200 µs, and the preset time interval is 2000 µs. Thus, the counting process can include 10 counting cycles, and the preset threshold can be 4 (or 3).

When the number of sine waves in any counting cycle is greater than or equal to 4, the high-frequency signal identifier 111 determines that the first input signal Is1 meets the frequency threshold (20 kHz) and outputs a conduction signal to the switch driver 12, enabling the switch driver 12 to activate the switch element 13 to execute the ballast mode.

Conversely, when the number of sine waves in each counting cycle is less than 4, the high-frequency signal identifier 111 determines that the first input signal Is1 does not meet the frequency threshold (20 kHz) and may be noise. At this point, the high-frequency signal identifier 111 enters a deadlock state without generating a conduction signal.

In another embodiment, the timer 1112 sets a counting cycle to 300 µs, and the preset time interval is 1500 µs. Thus, the counting process can include 5 counting cycles, and the preset threshold can be 6 (or 5). The sine wave period, counting cycle, preset time interval, and preset threshold mentioned above are examples and can be modified according to actual requirements.

Through the above circuit design, the high-frequency signal identifier 111 can achieve a highly efficient counting process, enabling the power controller 1 to effectively determine whether the first input signal Is1 is noise or a signal from the ballast GH, thereby preventing the power controller 1 from malfunctioning.

The embodiment just exemplifies the present invention and is not intended to limit the scope of the present invention; any equivalent modification and variation according to the spirit of the present invention is to be also included within the scope of the following claims and their equivalents.

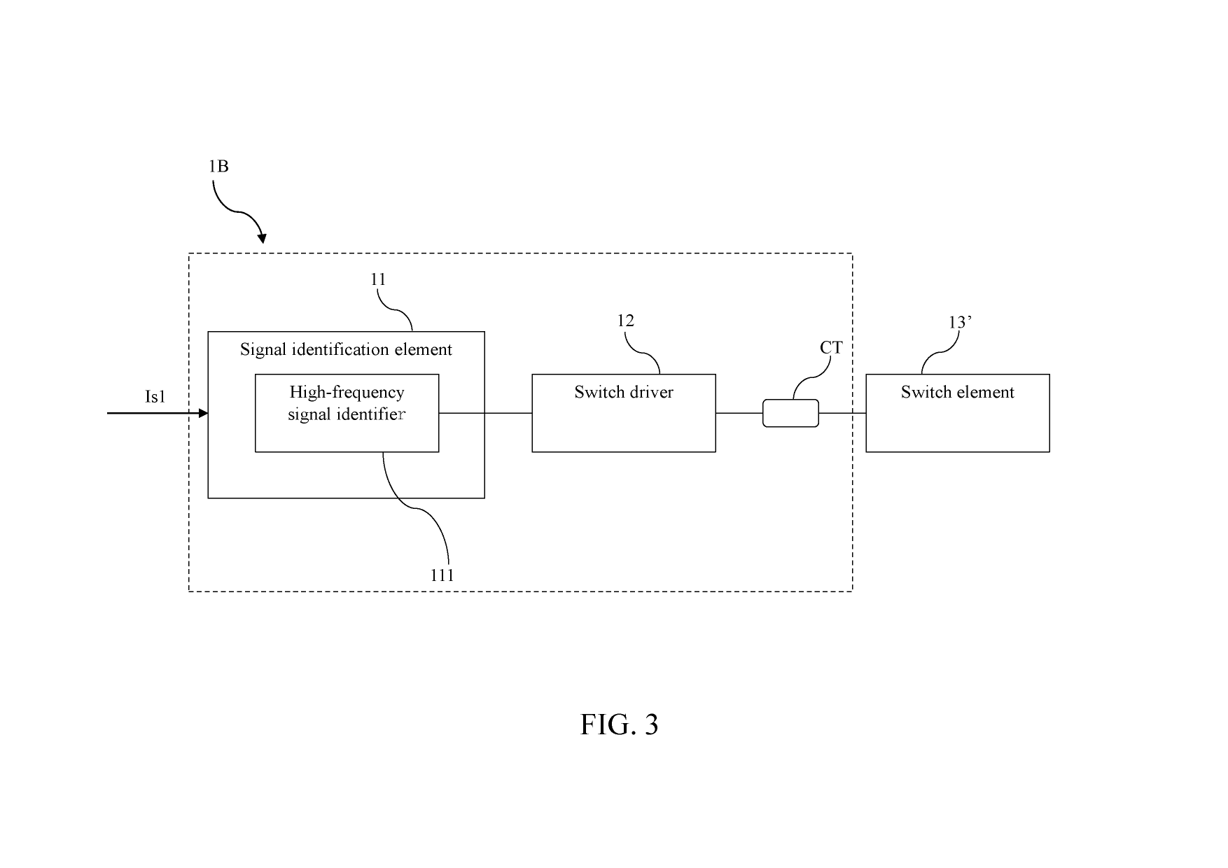

Please refer to FIG. 3, which is the block diagram of the circuit structure of the highly compatible power controller in accordance with the second embodiment of the present invention. As shown in FIG. 3, the power controller 1B includes a signal identification element 11 and a switch driver 12. The signal identification element 11 includes a high-frequency signal identifier 111. The switch driver 12 is connected to the high-frequency signal identifier 111. The functions of these components are the same as in the previous embodiment and will not be further elaborated here.

The difference between this embodiment and the first embodiment is that the power controller 1B further includes a port CT. The power controller 1B does not have a built-in switch element 13 but instead connects to an external switch element 13' via the port CT.

Similarly, the power controller 1B can execute the above-described counting process and decision logic to effectively determine whether the first input signal Is1 is a signal for the ballast GH or noise. When the power controller 1B determines that the first input signal Is1 is a signal from ballast GH, the power controller 1B operates in the ballast mode to drive the load. Conversely, when the power controller 1B determines that the first input signal Is1 is noise, the power controller 1B enters a deadlock state and does not generate a conduction signal.

The embodiment just exemplifies the present invention and is not intended to limit the scope of the present invention; any equivalent modification and variation according to the spirit of the present invention is to be also included within the scope of the following claims and their equivalents.

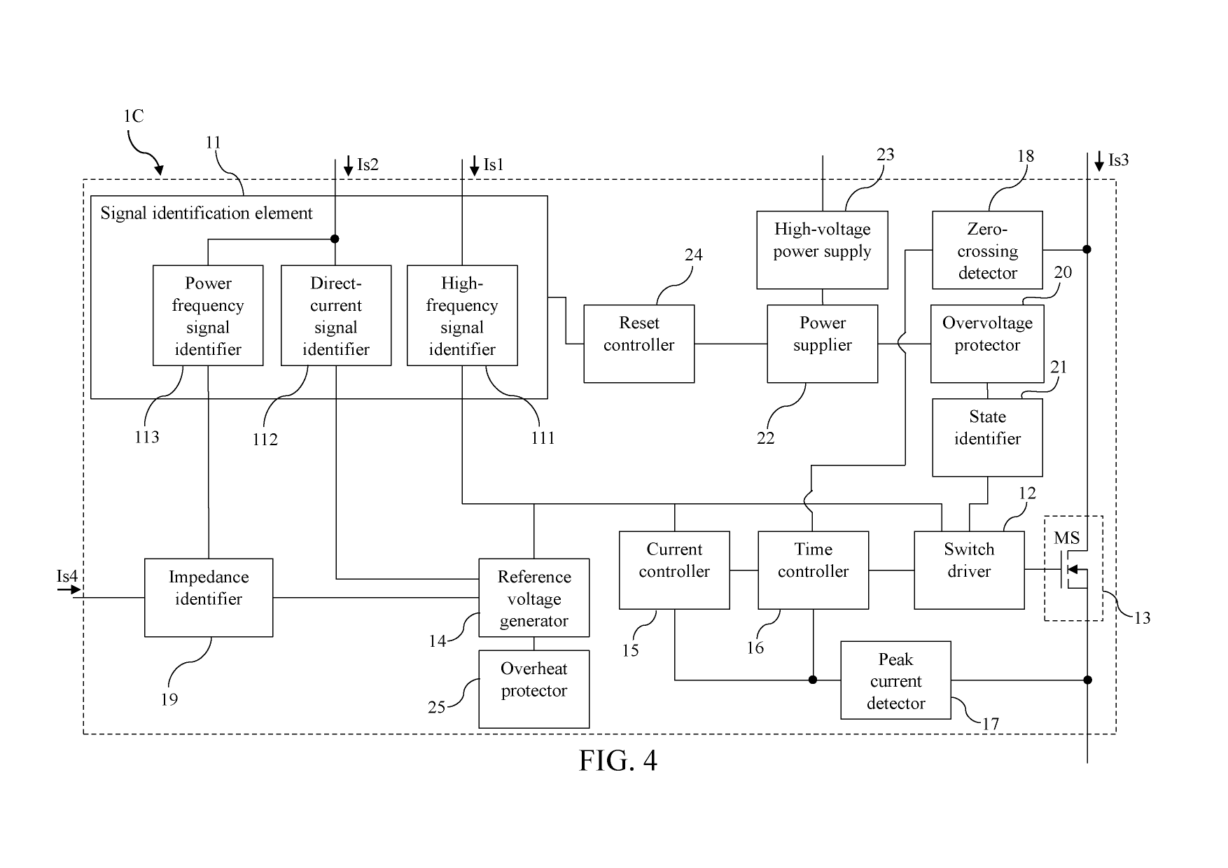

Please refer to FIG. 4, which is the block diagram of the circuit structure of the highly compatible power controller in accordance with the third embodiment of the present invention. As shown in FIG. 4, the power controller 1C includes a signal identification element 11, a switch driver 12, and a switch element 13. The signal identification element 11 includes a high-frequency signal identifier 111.

The difference between this embodiment and the first embodiment is that the signal identification element 11 further includes a direct-current signal identifier 112 and a power frequency (utility frequency) signal identifier 113. Additionally, the power controller 1C includes a reference voltage generator 14, a current controller 15, a time controller 16, a peak current detector 17, a zero-crossing detector 18, an impedance identifier 19, an overvoltage protector 20, a state identifier 21, a power supplier 22, a high-voltage power supply 23, a reset controller 24, and an overheat protector 25. Since the direct-current signal identifier 112, power frequency signal identifier 113, and other listed components have already been applied in currently available power controllers, the circuit structures thereof will not be further elaborated. Furthermore, in this embodiment, the switch element 13 is a transistor MS, which is a metal-oxide-semiconductor field-effect transistor.

The high-voltage power supply 23 is connected to the power supplier 22. The power supplier 22 is connected to the reset controller 24 and the overvoltage protector 20. The overvoltage protector 20 is connected to the state identifier 21. The state identifier 21 is connected to the switch driver 12.

The high-voltage power supply 23 divides the rectified DC voltage to generate a drive voltage. The power supplier 22 steps down and regulates the drive voltage. When the high-voltage power supply 23 is powered on, the reset controller 24 resets all components of the power controller 1C. The overvoltage protector 20 detects whether there is an overvoltage or undervoltage condition to generate a status detection signal. The state identifier 21 restarts or deadlocks the switch driver 12 according to the status detection signal.

The direct-current signal identifier 112 is connected to the reference voltage generator 14. The reference voltage generator 14 is connected to the current controller 15. The current controller 15 is connected to the time controller 16 and the peak current detector 17. The time controller 16 is connected to the zero-crossing detector 18, the peak current detector 17, and the switch driver 12.

The direct-current signal identifier 112 receives the second input signal Is2 and outputs a direct-current identification signal to the reference voltage generator 14 when determining that the second input signal Is2 is a direct-current signal, thereby generating a reference voltage. The peak current detector 17 detects the peak current when the switch element 13 is turned on and generates a peak current detection signal. The current controller 15 generates a current control signal according to the reference voltage and the peak current detection signal. The time controller 16 generates the first pulse-width modulation signal according to the current control signal, peak current detection signal, and the third input signal Is3 from the zero-crossing detector 18 to control the switch driver 12 in operating the switch element 13. This mode is the direct-current power mode (which is compatible with adapters, batteries, and other DC power sources).

The power frequency signal identifier 113 is connected to the impedance identifier 19. The impedance identifier 19 is connected to the reference voltage generator 14. The power frequency signal identifier 113 receives the second input signal Is2 and outputs a power frequency identification signal to the impedance identifier 19 when determining that the second input signal Is2 is a power frequency signal. The impedance identifier 19 outputs an impedance identification signal to the reference voltage generator 14 according to the fourth input signal Is4 to generate a reference voltage. The current controller 15 generates a current control signal according to the reference voltage and the peak current detection signal. The time controller 16 generates the second pulse-width modulation signal based on the current control signal, peak current detection signal, and zero-crossing detection signal to control the switch driver 12 in operating the switch element 13. This mode is the utility power mode (compatible with utility power).

The overheat protector 25 detects the temperature of the power controller 1C and transmits an overheat protection signal to the reference voltage generator 14 to reduce the reference voltage when the temperature exceeds a threshold value, thereby performing temperature regulation.

The power controller 1C can perform the utility power mode or the direct-current power mode through the aforementioned components. Therefore, the power controller 1C is compatible with ballast GH, utility power, and direct-current power sources (such as adapters and batteries) without requiring additional detection circuits, achieving high compatibility. Furthermore, the complexity of the drive circuit is thereby reduced, allowing the power controller 1C to be miniaturized and lowering manufacturing costs.

The embodiment just exemplifies the present invention and is not intended to limit the scope of the present invention; any equivalent modification and variation according to the spirit of the present invention is to be also included within the scope of the following claims and their equivalents.

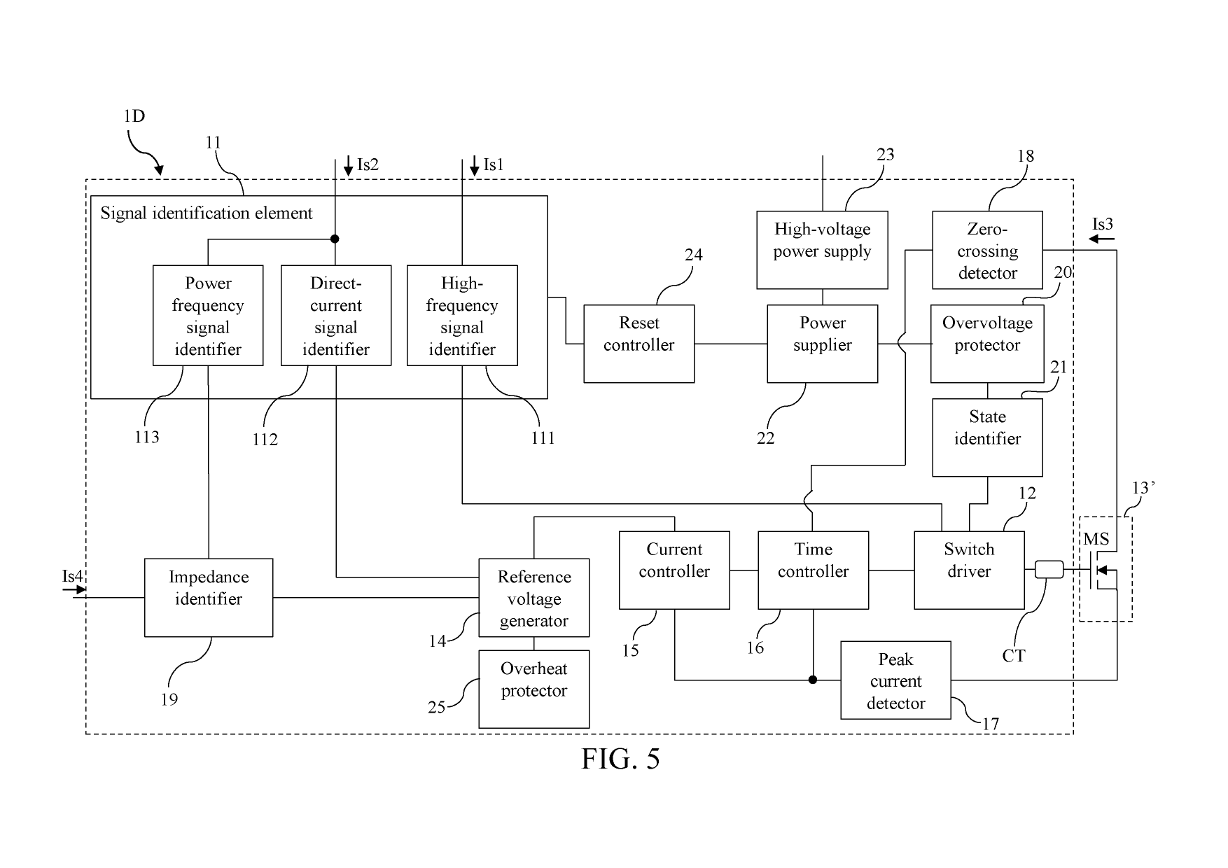

Please refer to FIG. 5, which is the block diagram of the circuit structure of the highly compatible power controller in accordance with the fourth embodiment of the present invention. As shown in FIG. 5, the power controller 1D includes a signal identification element 11, a switch driver 12, a reference voltage generator 14, a current controller 15, a time controller 16, a peak current detector 17, a zero-crossing detector 18, an impedance identifier 19, an overvoltage protector 20, a state identifier 21, a power supplier 22, a high-voltage power supply 23, a reset controller 24, and an overheat protector 25. The signal identification element 11 includes a high-frequency signal identifier 111, a direct-current signal identifier 112, and a power frequency signal identifier 113.

The functions of these components are the same as in the previous embodiments and will not be further elaborated. Unlike the third embodiment, the power controller 1D further includes a port CT. The power controller 1 does not have a built-in switch element 13 but instead connects to an external switch element 13' through the port CT. In this embodiment, the switch element 13' is a transistor MS, which is a metal-oxide-semiconductor field-effect transistor.

The embodiment just exemplifies the present invention and is not intended to limit the scope of the present invention; any equivalent modification and variation according to the spirit of the present invention is to be also included within the scope of the following claims and their equivalents.

As previously stated, according to one embodiment of the present invention, the power controller includes a signal identification element, a switch driver, a switch element. The signal identification element includes a high-frequency signal identifier for receiving a first input signal. The switch driver is connected to the high-frequency signal identifier. The switch element is connected to the switch driver. The high-frequency signal identifier executes a counting process within a preset time interval. The counting process includes a preset number of counting cycles for detecting the number of sine waves in the first input signal. The high-frequency signal identifier generates a conduction signal when the number of sine waves in any one of the counting cycles is greater than or equal to a preset threshold, and the switch driver activates the switch element according to the conduction signal. Through the above counting mechanism and the specialized decision-making logic thereof, the power controller can effectively determine whether the first input signal is a ballast signal and, if so, execute the ballast mode to drive the load. In this way, the power controller can be compatible with ballasts so as to meet actual requirements.

According to one embodiment of the present invention, the high-frequency signal identifier of the power controller enters a deadlock state, halting the counting process, when the number of sine waves in each counting cycle is less than the preset threshold. Via the above counting mechanism and the specialized decision-making logic thereof, the power controller can effectively determine whether the first input signal is noise. If the first input signal is determined to be noise (e.g., caused by poor external switch contact or other factors), the system enters a deadlock state and does not generate a conduction signal. Thus, the high-frequency signal identifier can effectively prevent the power controller from malfunctioning, ensuring high reliability.

Also, according to one embodiment of the present invention, the high-frequency signal identifier of the power controller comprises a counter, a timer, a resetter, and an executor. The resetter is connected to the counter and the timer, while the executor is connected to the counter and the timer. The timer controls the executor to generate an execution signal to direct the counter to execute the counting process and calculate the number of sine waves in the first input signal. The timer also controls the duration of each counting cycle and, at the end of each cycle, controls the resetter to generate a reset signal to reset the counter for the next cycle. Therefore, the high-frequency signal identifier can achieve a highly efficient counting process through a simple circuit design, enabling the power controller to effectively distinguish whether the first input signal is noise or a ballast signal.

Further, according to one embodiment of the present invention, the power controller further includes a reference voltage generator, a current controller, a time controller, a peak current detector, a zero-crossing detector, and an impedance identifier. The signal identification component also includes a direct-current signal identifier and a power frequency signal identifier. Thus, the power controller can execute either a utility power mode or a direct-current power mode through the above components. Consequently, the power controller is compatible with ballasts, utility power, and direct-current power sources (e.g., adapters, batteries) without requiring additional detection circuits, thereby achieving high compatibility. Moreover, the complexity of the driver circuit is reduced, enabling the power controller to achieve miniaturization and lower manufacturing costs.

Moreover, according to one embodiment of the present invention, the switch element of the power controller may also be an external switch element. The power controller can include a port through which the switch driver connects to the external switch element. Thus, the power controller can be configured with either an integrated switch element or an external switch element, depending on practical requirements, such that the power controller can conform to the requirements of different applications.

Furthermore, according to one embodiment of the present invention, the power controller can achieve the desired functionality through a simple circuit design and operational mechanism. As a result, it not only reduces manufacturing costs but also achieves the intended performance. This significantly enhances the practicality of the power controller, making it more versatile in application and more flexible in use. As described above, the highly compatible power controller according to the embodiments of the present invention can achieve great technical effects.

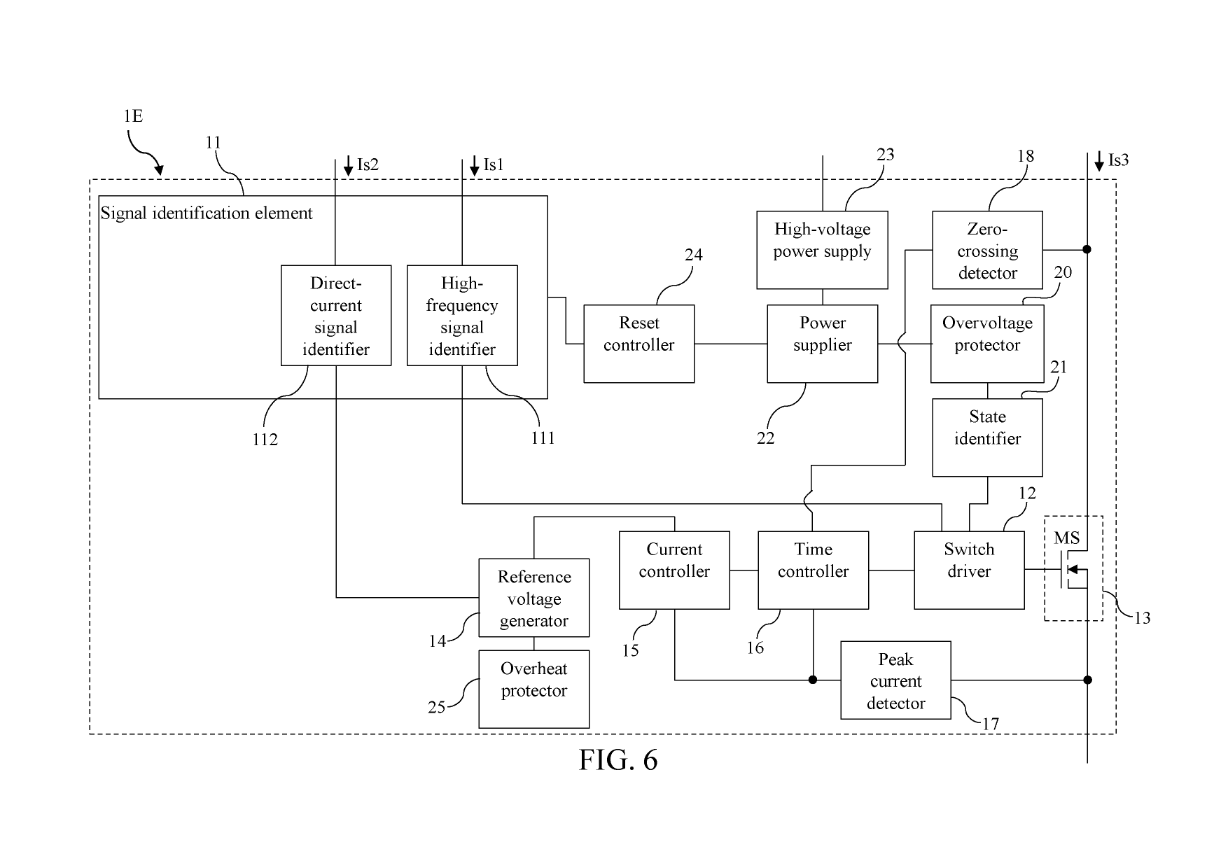

Please refer to FIG. 6, which is the block diagram of the circuit structure of the highly compatible power controller in accordance with the fifth embodiment of the present invention. As shown in FIG. 6, the difference between this embodiment and the third embodiment is that the signal identification element 11 of the power controller 1E includes a high-frequency signal identifier 111 and a direct-current signal identifier 112 but does not include a power frequency signal identifier 113. Additionally, the power controller 1E does not include an impedance identifier 19.

The embodiment just exemplifies the present invention and is not intended to limit the scope of the present invention; any equivalent modification and variation according to the spirit of the present invention is to be also included within the scope of the following claims and their equivalents.

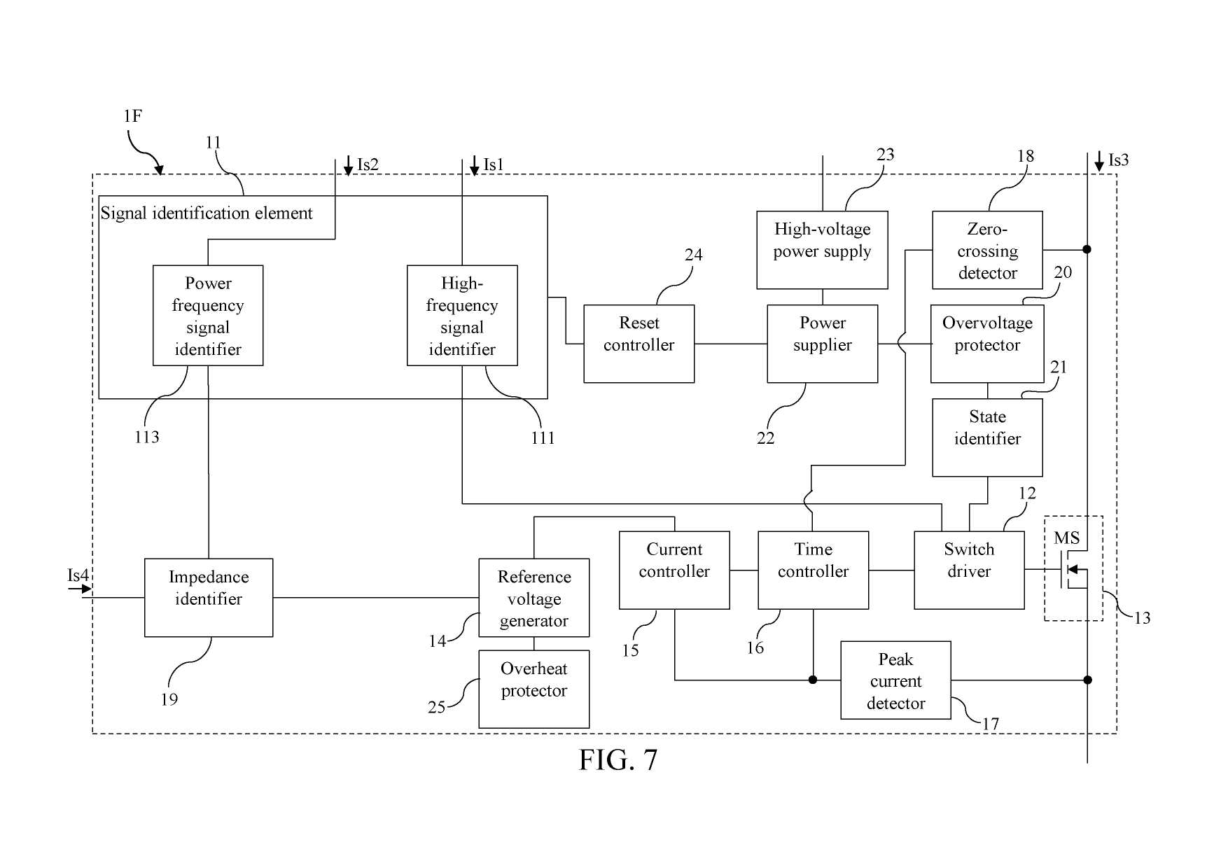

Please refer to FIG. 7, which is the block diagram of the circuit structure of the highly compatible power controller in accordance with the sixth embodiment of the present invention. As shown in FIG. 7, the difference between this embodiment and the third embodiment is that the signal identification element 11 of the power controller 1F includes a high-frequency signal identifier 111 and a power frequency signal identifier 113 but does not include a direct-current signal identifier 112.

The embodiment just exemplifies the present invention and is not intended to limit the scope of the present invention; any equivalent modification and variation according to the spirit of the present invention is to be also included within the scope of the following claims and their equivalents.

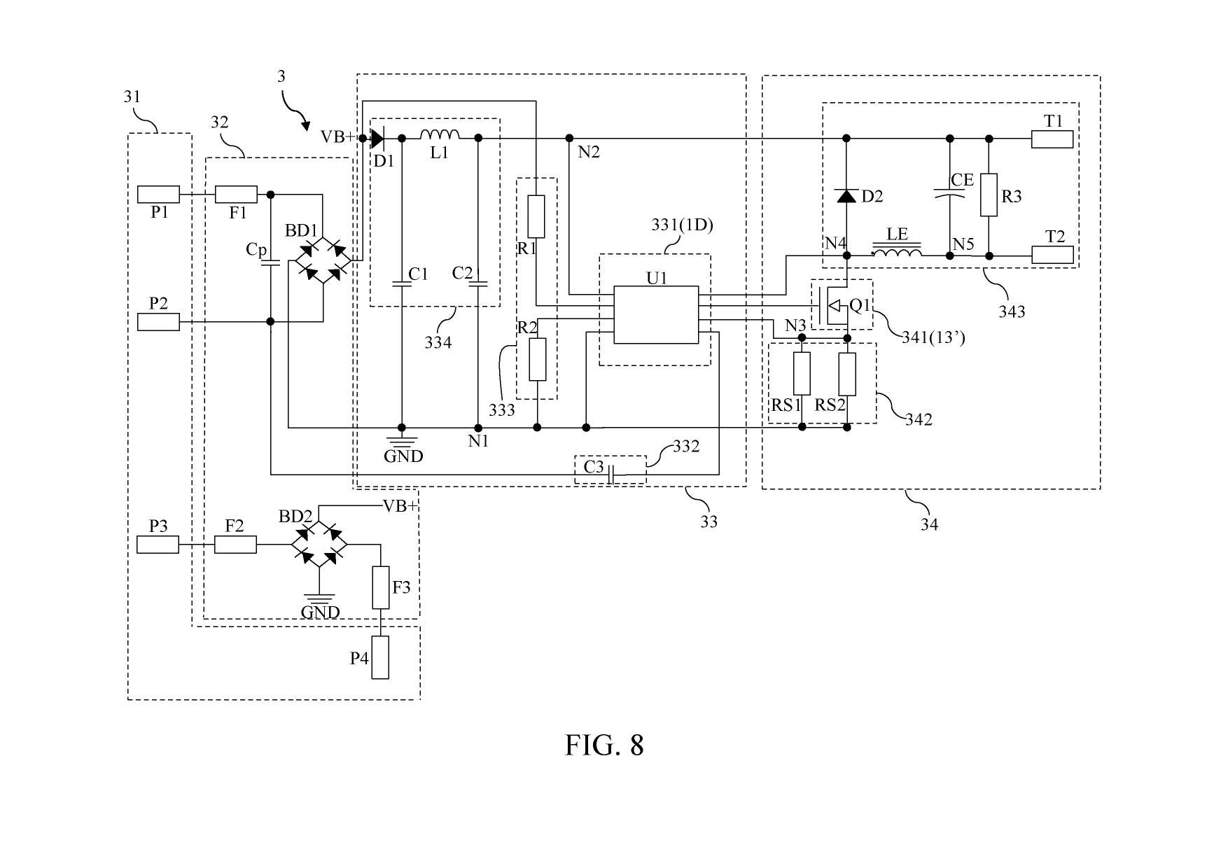

Please refer to FIG. 8, which is the circuit diagram of the lighting device driver having the power controller in accordance with the sixth embodiment of the present invention. FIG. 8 provides an example of the circuit structure of the lighting device driver 3. This embodiment is for illustrative purposes only; the circuit structures of the input module 31, rectification module 32, driving control module 33, and power conversion module 34 can be modified as needed, and the invention is not limited thereto. As shown in FIG. 8, the lighting device driver 3 includes an input module 31, a rectification module 32, a driving control module 33, and a power conversion module 34.

The input module 31 includes a first input terminal P1, a second input terminal P2, a third input terminal P3, and a fourth input terminal P4.

The rectification module 32 is connected to the input module 31 and includes a first rectifier BD1, a second rectifier BD2, a first fuse F1, a second fuse F2, a third fuse F3, and a capacitor Cp. The first end of the first rectifier BD1 is connected to the second input terminal P2; the second end of the first rectifier BD1 is connected to the rectified signal output terminal VB+; the third end of the first rectifier BD1 is connected to the first input terminal P1 via the first fuse F1; and the fourth end of the first rectifier BD1 is connected to the first node N1. The first node N1 is connected to the ground GND. The first end of the second rectifier BD2 is connected to the fourth input terminal P4 via the third fuse F3; the second end of the second rectifier BD2 is connected to the rectified signal output terminal VB+; the third end of the second rectifier BD2 is connected to the third input terminal P3 via the second fuse F2; and the fourth end of the second rectifier BD2 is connected to the ground GND. In one embodiment, the first rectifier BD1 and the second rectifier BD2 can be bridge rectifiers (full-wave or half-wave rectifiers). In another embodiment, they can also be bipolar junction transistors, circuits incorporating bipolar junction transistors, or any other currently available circuits or electronic components with rectification functions.

The driving control module 33 is connected to the rectification module 32 and includes a control unit 331, a signal identification unit 332, an impedance identification and detection unit 333, and a direct-current signal smoothing unit 334, which are connected to each other. The control unit 331 may have at least one signal identification interface and is connected to the signal identification unit 332 via this interface. The control unit 331 includes a controller U1, which may serve as the power controller 1D of the fourth embodiment (the power controller 1D of the fourth embodiment is connected to an external switch element 13’). The direct-current signal smoothing unit 334 includes a first diode D1, an inductor L1, a first capacitor C1, and a second capacitor C2. The anode of the first diode D1 is connected to the rectified signal output terminal VB+, and the cathode thereof is connected to one end of the inductor L1, which is further connected to the first node N1 via the first capacitor C1. The other end of the inductor L1 is connected to the second node N2, which is further connected to the first node N1 via the second capacitor C2. The impedance identification and detection unit 333 includes a plurality of resistors connected in series. In this embodiment, the impedance identification and detection unit 333 includes a first resistor R1 and a second resistor R2. The two ends of the first resistor R1 are connected to the rectified signal output terminal VB+ and the control unit 331, respectively. The two ends of the second resistor R2 are connected to the control unit 331 and the first node N1, respectively. The signal identification unit 332 includes a third capacitor C3, which is connected to the first input terminal P1 via the capacitor Cp, enabling a portion of the input signal Is’, to couple to the third capacitor C3 (the signal identification unit 332). In another embodiment, the control unit 331 may also serve as the power controller 1A, 1B, 1C, 1E, or 1F of the first, second, third, fifth, or sixth embodiments.

The power conversion module 34 is connected to the control unit 331. The power conversion module 34 includes a switching unit 341, a sampling unit 342, and an output unit 343. The switching unit 341 includes a switch Q1 (which serves as the external switch element 13’ of the fourth embodiment), and may be a metal-oxide-semiconductor field-effect transistor. Alternatively, the switch Q1 can also be a bipolar junction transistor or other similar components. The first end of the switch Q1 is connected to the control unit 331, the second end of the switch Q1 is connected to the third node N3, and the third end of the switch Q1 is connected to the fourth node N4. Both the third node N3 and the fourth node N4 are connected to the control unit 331. The output unit 343 includes a second diode D2, an energy storage inductor LE, an electrolytic capacitor CE, a third resistor R3, a first output terminal T1, and a second output terminal T2. The anode and cathode of the second diode D2 are connected to the fourth node N4 and the second node N2, respectively. The two ends of the energy storage inductor LE are connected to the fourth node N4 and the fifth node N5, respectively. The two ends of the electrolytic capacitor CE are connected to the fifth node N5 and the second node N2, respectively. The two ends of the third resistor R3 are connected to the fifth node N5 and the second node N2, respectively. The second node N2 and the fifth node N5 are connected to the first output terminal T1 and the second output terminal T2, respectively.

The embodiment just exemplifies the present invention and is not intended to limit the scope of the present invention; any equivalent modification and variation according to the spirit of the present invention is to be also included within the scope of the following claims and their equivalents.

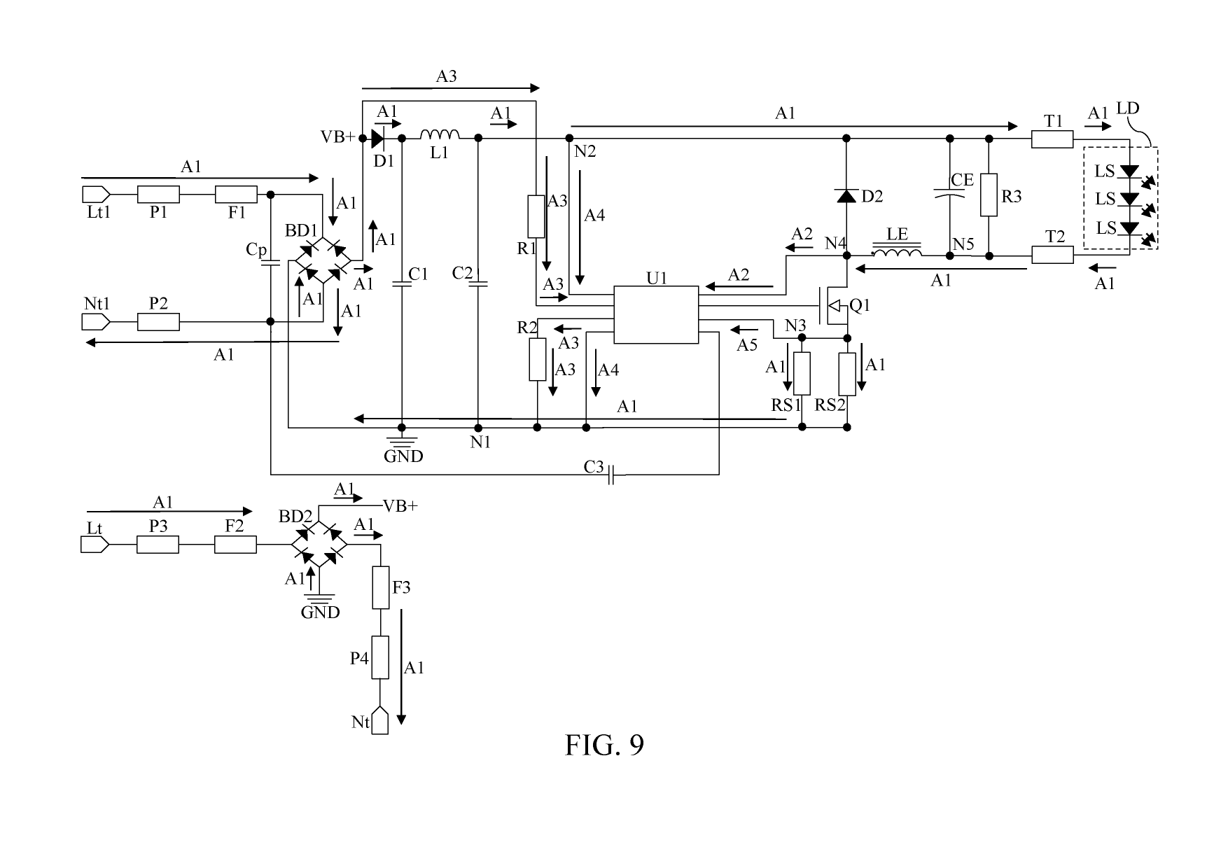

Please refer to FIG. 9, which is the schematic view of the utility power mode of the lighting device driver having the power controller in accordance with the sixth embodiment of the present invention. As shown in FIG. 9, the load LD includes a plurality of light sources LS, which may be light-emitting diodes. The load LD is connected to the first output terminal T1 and the second output terminal T2 of the output unit 343. When the input module 31 is connected to the utility power (Lt1, Nt1, Lt, and Nt represent the output terminals of the utility power), the input module 31 couples the external input signal Is, and the rectification module 32 rectifies the input signal Is to generate a rectified signal. The impedance identification and detection unit 333 of the driving control module 33 detects the impedance of the rectified signal, as indicated by the arrow A3 (this signal corresponds to the second input signal Is2 in the fourth embodiment). The control unit 331 executes the utility power mode when the control unit 331 determines that the second input signal Is2 is a power frequency signal. The direct-current signal smoothing unit 334 converts the rectified signal into a smooth direct-current signal (used to drive the high-voltage power supply 23 in the fourth embodiment) to supply power to the driving control module 33, as indicated by the arrow A4. The sampling unit 342 of the power conversion module 34 generates a feedback signal according to the peak current during the conduction of the switch element 341. The control unit 331 adjusts the pulse-width modulation signal according to the feedback signal (this feedback signal is inputted to the peak current detector 17 in the fourth embodiment) to control the power conversion module 34 for power conversion, as indicated by the arrow A5. In this case, the switch element 341 is continuously turned on and off, allowing the power conversion module 34 to perform power conversion. The control unit 331 can also receive a zero-crossing detection signal from the fourth node N4, as indicated by arrow A2 (this signal corresponds to the third input signal Is3 in the fourth embodiment), to perform zero-crossing detection. The rectified signal drives the load LD via the power conversion module 34 (including the switch element 341, output unit 343, and sampling unit 342). The path of the rectified signal is shown by the arrow A1. The lighting device driver 3 can also operate in a direct-current power mode.

The embodiment just exemplifies the present invention and is not intended to limit the scope of the present invention; any equivalent modification and variation according to the spirit of the present invention is to be also included within the scope of the following claims and their equivalents.

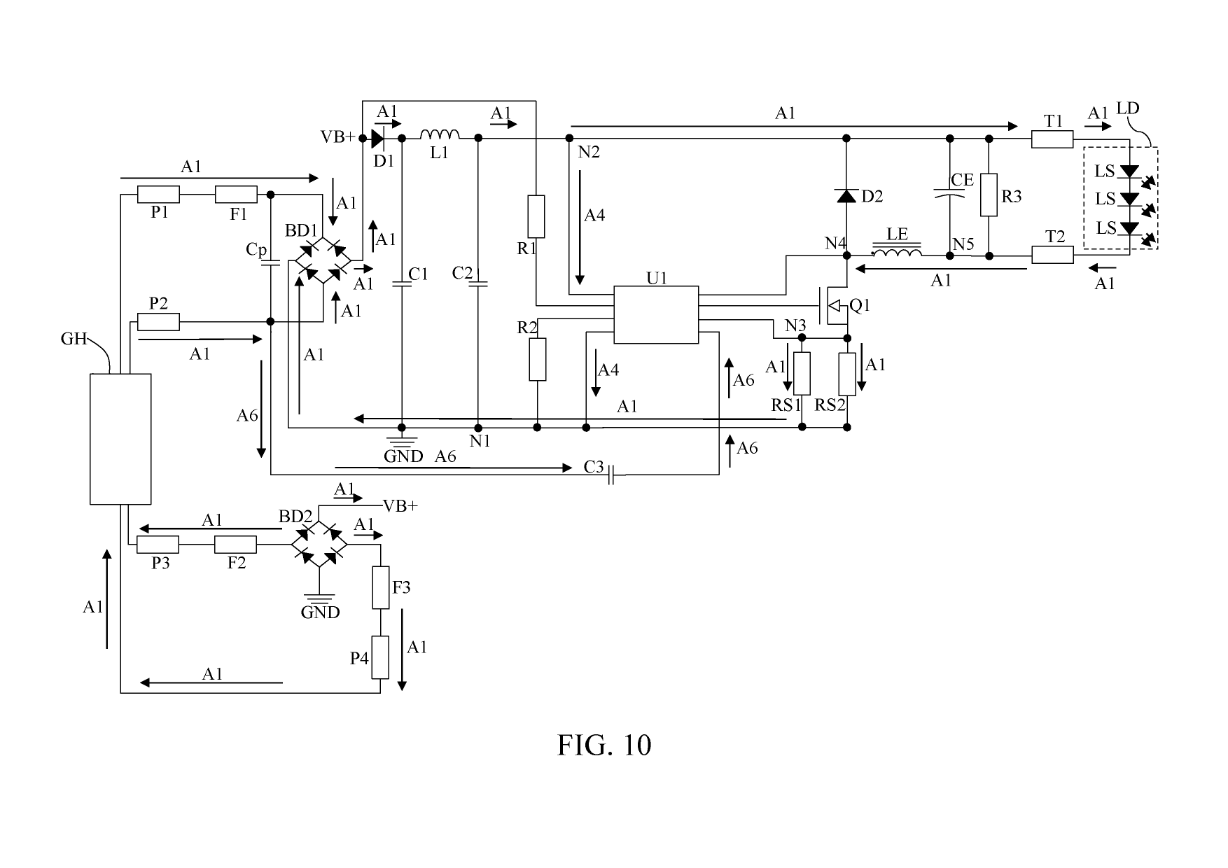

Please refer to FIG. 10, which is the schematic view of the ballast mode of the lighting device driver having the power controller in accordance with the sixth embodiment of the present invention. As shown in FIG. 10, the load LD includes a plurality of light sources LS, which may be light-emitting diodes. The load LD is connected to the first output terminal T1 and the second output terminal T2 of the output unit 343. When the input module 31 is connected to the ballast GH, the input module 31 generates an input signal Is, and the rectification module 32 rectifies the input signal Is to generate a rectified signal. A portion of the input signal Is’ is coupled to the signal identification unit 332 via the capacitor Cp of the rectification module 32 (this signal corresponds to the first input signal Is1 in the fourth embodiment), as indicated by the arrow A6. The control unit 331 enters the ballast mode when the counting process identifies the signal as originating from the ballast GH. In the ballast mode, the control unit 331 generates a direct-current signal to control the continuous conduction of the switch element in the power conversion module 34. In this case, the switch element 341 remains in a continuously conducting state, forming a closed-loop circuit. Consequently, the rectified signal generated from the input signal of the ballast GH can directly drive the load LD. The direct-current signal smoothing unit 334 converts the rectified signal into a smooth direct-current signal to supply power to the driving control module 33, as indicated by the arrow A4. he rectified signal drives the load LD after being further smoothed via the power conversion module 34 (including the switch element 341, output unit 343, and sampling unit 342). The path of the rectified signal Rs is shown by the arrow A1.

The embodiment just exemplifies the present invention and is not intended to limit the scope of the present invention; any equivalent modification and variation according to the spirit of the present invention is to be also included within the scope of the following claims and their equivalents.

To sum up, according to one embodiment of the present invention, the power controller includes a signal identification element, a switch driver, a switch element. The signal identification element includes a high-frequency signal identifier for receiving a first input signal. The switch driver is connected to the high-frequency signal identifier. The switch element is connected to the switch driver. The high-frequency signal identifier executes a counting process within a preset time interval. The counting process includes a preset number of counting cycles for detecting the number of sine waves in the first input signal. The high-frequency signal identifier generates a conduction signal when the number of sine waves in any one of the counting cycles is greater than or equal to a preset threshold, and the switch driver activates the switch element according to the conduction signal. Through the above counting mechanism and the specialized decision-making logic thereof, the power controller can effectively determine whether the first input signal is a ballast signal and, if so, execute the ballast mode to drive the load. In this way, the power controller can be compatible with ballasts so as to meet actual requirements.

According to one embodiment of the present invention, the high-frequency signal identifier of the power controller enters a deadlock state, halting the counting process, when the number of sine waves in each counting cycle is less than the preset threshold. Via the above counting mechanism and the specialized decision-making logic thereof, the power controller can effectively determine whether the first input signal is noise. If the first input signal is determined to be noise (e.g., caused by poor external switch contact or other factors), the system enters a deadlock state and does not generate a conduction signal. Thus, the high-frequency signal identifier can effectively prevent the power controller from malfunctioning, ensuring high reliability.

Also, according to one embodiment of the present invention, the high-frequency signal identifier of the power controller comprises a counter, a timer, a resetter, and an executor. The resetter is connected to the counter and the timer, while the executor is connected to the counter and the timer. The timer controls the executor to generate an execution signal to direct the counter to execute the counting process and calculate the number of sine waves in the first input signal. The timer also controls the duration of each counting cycle and, at the end of each cycle, controls the resetter to generate a reset signal to reset the counter for the next cycle. Therefore, the high-frequency signal identifier can achieve a highly efficient counting process through a simple circuit design, enabling the power controller to effectively distinguish whether the first input signal is noise or a ballast signal.

Further, according to one embodiment of the present invention, the power controller further includes a reference voltage generator, a current controller, a time controller, a peak current detector, a zero-crossing detector, and an impedance identifier. The signal identification component also includes a direct-current signal identifier and a power frequency signal identifier. Thus, the power controller can execute either a utility power mode or a direct-current power mode through the above components. Consequently, the power controller is compatible with ballasts, utility power, and direct-current power sources (e.g., adapters, batteries) without requiring additional detection circuits, thereby achieving high compatibility. Moreover, the complexity of the driver circuit is reduced, enabling the power controller to achieve miniaturization and lower manufacturing costs.

Moreover, according to one embodiment of the present invention, the switch element of the power controller may also be an external switch element. The power controller can include a port through which the switch driver connects to the external switch element. Thus, the power controller can be configured with either an integrated switch element or an external switch element, depending on practical requirements, such that the power controller can conform to the requirements of different applications.

Furthermore, according to one embodiment of the present invention, the power controller can achieve the desired functionality through a simple circuit design and operational mechanism. As a result, it not only reduces manufacturing costs but also achieves the intended performance. This significantly enhances the practicality of the power controller, making it more versatile in application and more flexible in use.

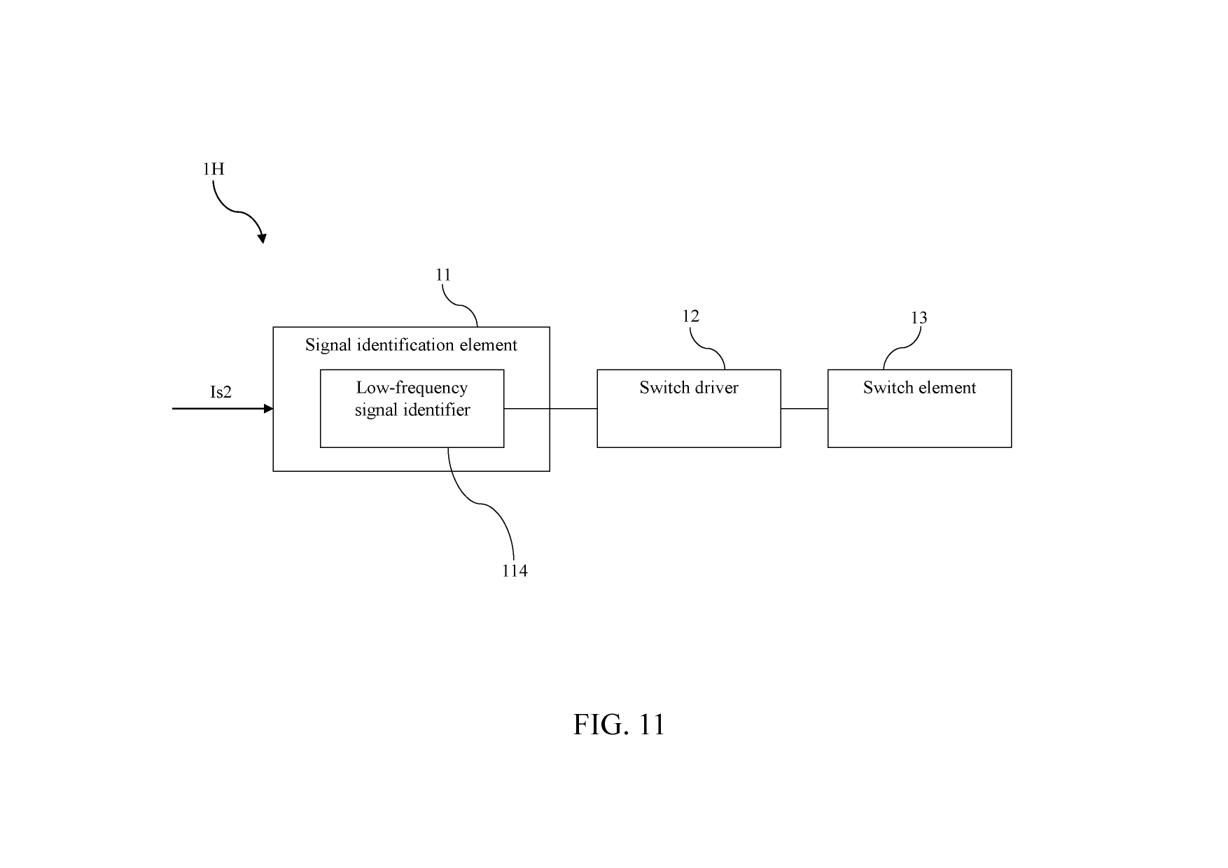

Please refer to FIG. 11, which is the block diagram of the circuit structure of the highly compatible power controller in accordance with the seventh embodiment of the present invention. As shown in FIG. 11, the power controller 1H includes a signal identification component 11, a switch driver 12, and a switching element 13.

The signal identification component 11 includes a low-frequency signal identifier 114. The low-frequency signal identifier 114 receives a second input signal Is2.

The switch driver 12 is connected to the low-frequency signal identifier 114. In this embodiment, the switch driver 12 may be a gate driver. In another embodiment, the switch driver 12 may be a signal amplifier or other components with signal amplification capabilities.

The switch element 13 is connected to the switch driver 12. In this embodiment, the switch element 13 may be a metal-oxide-semiconductor field-effect transistor (MOSFET). In another embodiment, the switch element 13 may also be a bipolar junction transistor (BJT) or other similar components.

The embodiment just exemplifies the present invention and is not intended to limit the scope of the present invention; any equivalent modification and variation according to the spirit of the present invention is to be also included within the scope of the following claims and their equivalents.

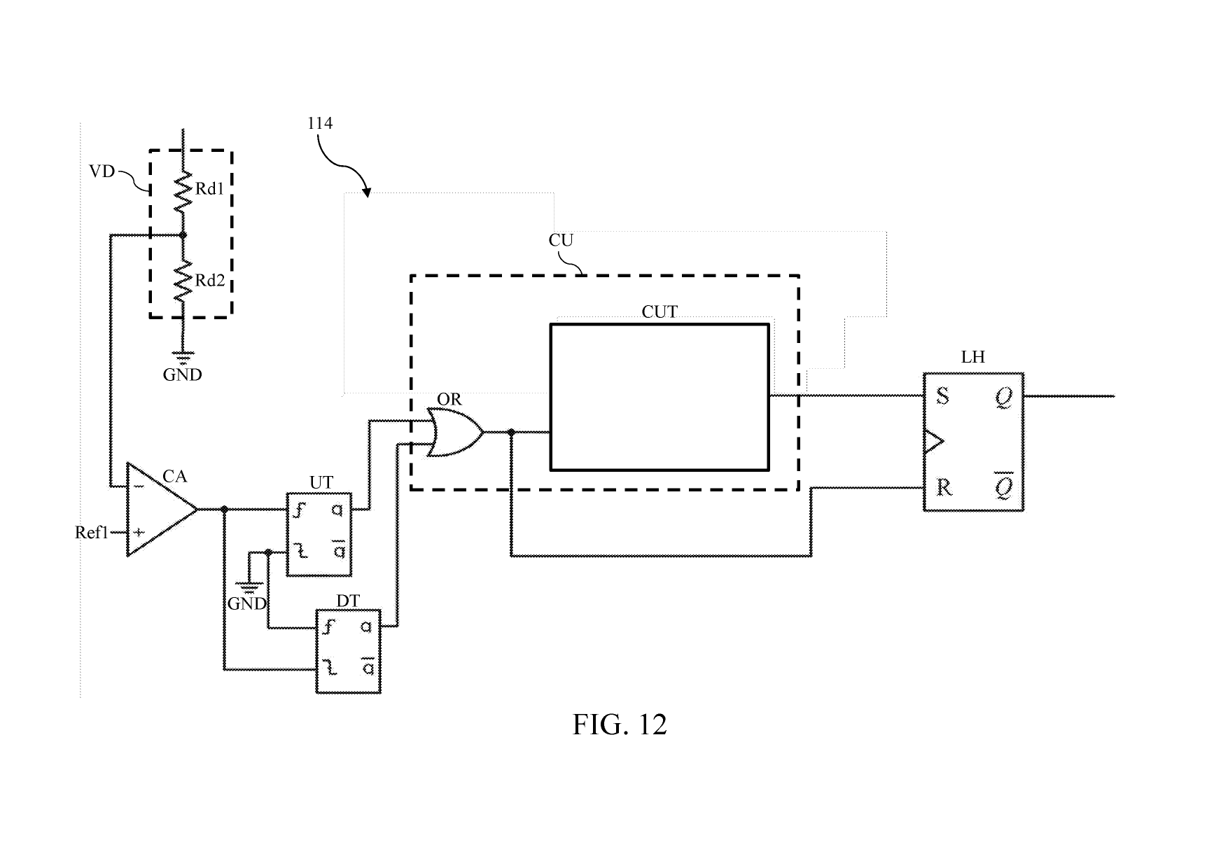

Please refer to FIG. 12, which is the circuit diagram the low-frequency signal identifier of the highly compatible power controller in accordance with the seventh embodiment of the present invention. As shown in FIG. 12, the low-frequency signal identifier 114 includes a voltage divider VD, a comparator CA, a rising-edge trigger UT, a falling-edge trigger DT, a counting unit CU, and a latch LH.

The voltage divider VD is connected to the comparator CA. The voltage divider VD includes a first divider resistor Rd1 and a second divider resistor Rd2 connected in series with each other. One end of the first divider resistor Rd1 serves as the terminal of receiving a second input signal Is2. One end of the second divider resistor Rd2 is connected to the other end of the first divider resistor Rd1 and is further connected to the input terminal of the comparator CA, and the other end of the second divider resistor Rd2 is connected to a ground terminal GND. The circuit structure of the voltage divider VD may be modified according to actual requirements. Such a circuit structure of the voltage divider VD is well known to those skilled in the art and is therefore not described in detail herein.

One input terminal of the rising-edge trigger UT is connected to the output terminal of the comparator CA, and the other input terminal of the rising-edge trigger UT is connected to the ground terminal GND. One input terminal of the falling-edge trigger DT is connected to the output terminal of the comparator CA, and the other input terminal of the falling-edge trigger DT is connected to the ground terminal GND.

The counting unit CU includes a counting element CUT and an OR gate OR. The two input terminals of the OR gate OR are respectively connected to the rising-edge trigger UT and the falling-edge trigger DT. The input terminal of the counting element CUT is connected to the output terminal of the OR gate OR. The counting element CUT may be a counter.

The two input terminals of the latch LH are respectively connected to the output terminal of the counting element CUT and the output terminal of the OR gate OR.

The embodiment just exemplifies the present invention and is not intended to limit the scope of the present invention; any equivalent modification and variation according to the spirit of the present invention is to be also included within the scope of the following claims and their equivalents.

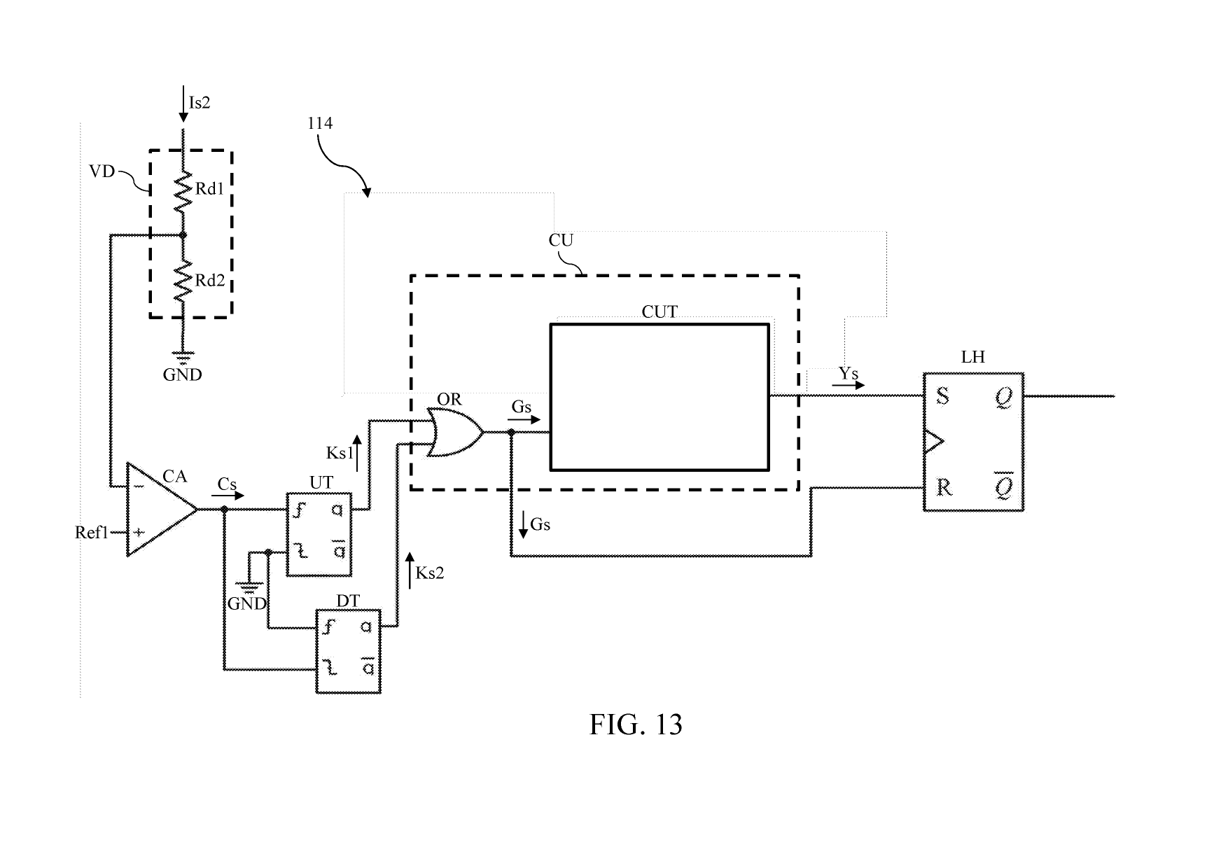

Please refer to FIG. 13, which is the schematic view illustrating the operating state of the low-frequency signal identifier of the highly compatible power controller in accordance with the seventh embodiment of the present invention. As shown in FIG. 13, the voltage divider VD receives the second input signal Is2 to perform voltage division. The comparator CA receives the second input signal Is2 and compares the second input signal Is2 with a first reference voltage Ref1 to generate a comparison signal Cs. The rising-edge trigger UT and the falling-edge trigger DT receive the comparison signal Cs and respectively generate output signals Ks1 and Ks2. The OR gate OR generates a logic signal Gs according to the output signal Ks1 of the rising-edge trigger UT and the output signal Ks of the falling-edge trigger DT. The counting element CUT generates a count output signal Ys according to the logic signal Gs. Thereafter, the latch LH determines whether the second input signal Is2 is a direct-current signal or a power frequency signal according to the logic signal Gs and the count output signal Ys, so as to control the switch driver 12 to control the switching element 13.

When the second input signal Is2 is a direct-current signal, neither the rising-edge trigger UT nor the falling-edge trigger DT is triggered. At this time, the output signals Ks1 and Ks2 of the rising-edge trigger UT and the falling-edge trigger DT are both at low level. Accordingly, the logic signal Gs output by the OR gate OR is a low-level signal. Under such conditions, the counting element CUT continuously performs counting and generates the count output signal Ys at high level after a count value reaches a count upper limit. When the logic signal Gs is at low level and the count output signal Ys is at high level, the latch LH determines that the second input signal Is2 is a direct-current signal according to the logic signal Gs and the count output signal Ys, and generates a direct-current identification signal. In this embodiment, the count upper limit may be 40 ms. In another embodiment, the count upper limit may also be 50 ms or 60 ms, and may be adjusted according to actual requirements.

When the second input signal Is2 is a power frequency signal, both the rising-edge trigger UT and the falling-edge trigger DT are triggered. At this time, the output signal Ks1 of the rising-edge trigger UT includes both high-level and low-level signals, and the output signal Ks2 of the falling-edge trigger DT also includes both high-level and low-level signals. Accordingly, the logic signal Gs output by the OR gate OR is a high-level signal. Under such conditions, the counting element CUT is reset and generates the count output signal Ys at low level. When the logic signal Gs is at high level and the count output signal Ys is at low level, the latch LH determines that the second input signal Is2 is a power frequency signal according to the logic signal Gs and the count output signal Ys, and generates a power frequency identification signal.

As can be understood from the foregoing, in this embodiment, the low-frequency signal identifier 114 of the power controller 1H adopts a simple logic determination circuit based on a counting mechanism, which does not require a voltage comparison circuit formed of discrete components. Accordingly, the low-frequency signal identifier 114 is not readily affected by temperature drift or component aging, while still achieving accurate determination results. Therefore, the power controller can satisfy actual requirements.

In addition, in this embodiment, the low-frequency signal identifier 114 of the power controller 1H adopts a special logic determination mechanism based on counting results, which can accurately determine whether the second input signal Is2 is a direct-current signal or a power frequency signal according to a type of the logic signal and the counting result, without requiring high-precision sampling circuits or complex signal processing and comparison algorithms. Accordingly, the power controller 1H can significantly reduce hardware resource requirements and can avoid response delay issues. As a result, the performance of the power controller 1H can be substantially improved to satisfy the requirements of various applications.

The embodiment just exemplifies the present invention and is not intended to limit the scope of the present invention; any equivalent modification and variation according to the spirit of the present invention is to be also included within the scope of the following claims and their equivalents.

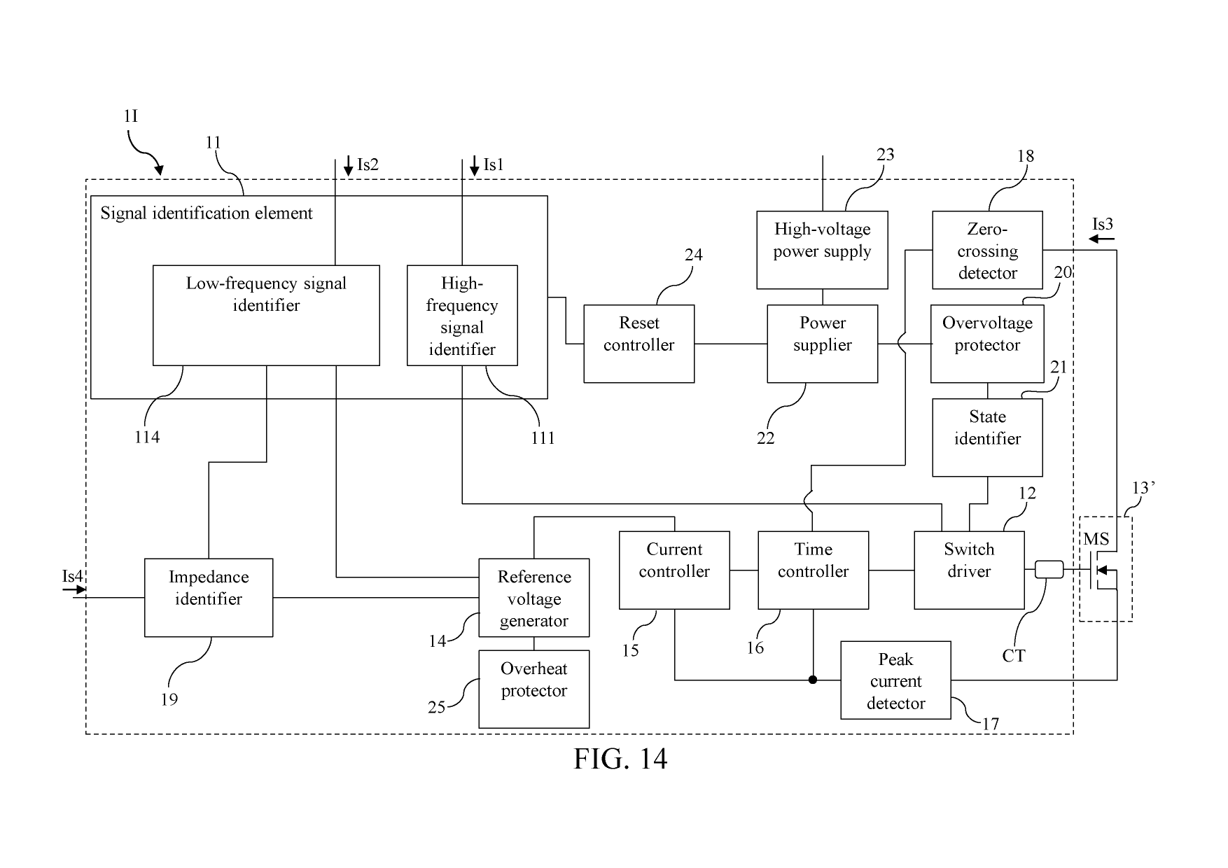

Please refer to FIG. 14, which is the block diagram of the circuit structure of the highly compatible power controller in accordance with the eighth embodiment of the present invention. As shown in FIG. 14, the power controller 1I includes the signal identification component 11, the switch driver 12, and the switching element 13. The signal identification component 11 includes the low-frequency signal identifier 114.

In addition, the signal identification component 11 further includes a high-frequency signal identifier 111. Moreover, the power controller 1 further includes a reference voltage generator 14, a current controller 15, a time controller 16, a peak current detector 17, a zero-crossing detector 18, an impedance identifier 19, an overvoltage protector 20, a state identifier 21, a power supplier 22, a high-voltage power supply 23, a reset controller 24, and an overheat protector 25. The operating mechanisms of the above components are the same as those described in the foregoing embodiments and are therefore not described in detail herein.

As described above, the high-frequency signal identifier 111 determines that a first input signal Is1 meets a frequency threshold (20 kHz) and outputs a conduction signal to the switch driver 12, enabling the switch driver 12 to activate the switch element 13 to execute the ballast mode.

Similarly, when the low-frequency signal identifier 114 receives a second input signal Is2 and outputs a direct-current identification signal to the reference voltage generator 14 when determining that the second input signal Is2 is a direct-current signal, thereby generating a reference voltage. The peak current detector 17 detects the peak current when the switch element 13 is turned on and generates a peak current detection signal. The current controller 15 generates a current control signal according to the reference voltage and the peak current detection signal. The time controller 16 generates the first pulse-width modulation signal according to the current control signal, peak current detection signal, and the third input signal Is3 from the zero-crossing detector 18 to control the switch driver 12 in operating the switch element 13. This mode is the direct-current power mode (which is compatible with adapters, batteries, and other DC power sources).

On the other hand, when the low-frequency signal identifier 114 receives the second input signal Is2 and outputs a power frequency identification signal to the impedance identifier 19 when determining that the second input signal Is2 is a power frequency signal. The impedance identifier 19 outputs an impedance identification signal to the reference voltage generator 14 according to the fourth input signal Is4 to generate a reference voltage. The current controller 15 generates a current control signal according to the reference voltage and the peak current detection signal. The time controller 16 generates the second pulse-width modulation signal based on the current control signal, peak current detection signal, and zero-crossing detection signal to control the switch driver 12 in operating the switch element 13. This mode is the utility power mode (compatible with utility power).

The embodiment just exemplifies the present invention and is not intended to limit the scope of the present invention; any equivalent modification and variation according to the spirit of the present invention is to be also included within the scope of the following claims and their equivalents.

It is worthy to point out that currently available lighting devices require additional detection circuits, such as voltage comparison circuits formed of discrete components. Such circuits are susceptible to temperature drift and component aging, and prolonged operation may cause a shift in a comparison threshold, thereby resulting in misidentification of a power source type. Such designs not only increase hardware cost and circuit complexity, but may also adversely affect the accuracy and real-time performance of the determination result. In addition, some currently available lighting devices distinguish power source types by analyzing waveform characteristics of an input voltage. However, such methods typically require high-precision sampling circuits and complex signal processing and comparison algorithms, thereby imposing relatively high demands on hardware resources. Moreover, during instantaneous power source switching, response delay is likely to occur. By contrast, according to one embodiment of the present invention, the power controller includes a signal identification element, a switch driver, a switch element. The signal identification element includes a low-frequency signal identifier. The low-frequency signal identifier includes a comparator, a rising-edge trigger, a falling-edge trigger, a counting unit, and a latch. The comparator receives a second input signal and to compare the second input signal with a first reference voltage to generate a comparison signal. The rising-edge trigger and the falling-edge trigger receive the comparison signal. The counting unit includes a counting element and an OR gate. The OR gate generates a logic signal according to the outputs of the rising-edge trigger and the falling-edge trigger, and the counting element generates a count output signal according to the logic signal. The latch determines whether the second input signal is a direct-current signal or a power-frequency signal according to the logic signal and the count output signal so as to control the switch driver to control the switch element. As set forth above, the low-frequency signal identifier of the power controller adopts a simple logic determination circuit based on a counting mechanism, which does not require a voltage comparison circuit formed of discrete components. Accordingly, the low-frequency signal identifier is not readily affected by temperature drift or component aging, while still achieving accurate determination results. Therefore, the power controller can satisfy actual requirements.

Further, according to one embodiment of the present invention, when the logic signal is at low level, the counting element performs counting and generates the count output signal at high level after a count value reaches a count upper limit. The latch determines that the second input signal is a direct-current signal according to the logic signal and the count output signal, and generates a direct-current identification signal. When the logic signal is at high level, the counting element is reset and generates the count output signal at low level. The latch determines that the second input signal is a power frequency signal according to the logic signal and the count output signal, and generates a power frequency identification signal. As described above, the low-frequency signal identifier of the power controller adopts a special logic determination mechanism based on counting results, which can accurately determine whether the second input signal is a direct-current signal or a power frequency signal according to a type of the logic signal and the counting result, without requiring high-precision sampling circuits or complex signal processing and comparison algorithms. Accordingly, the power controller can significantly reduce hardware resource requirements and can avoid response delay issues. As a result, the performance of the power controller can be substantially improved to satisfy the requirements of various applications.

Moreover, according to one embodiment of the present invention, the power controller can achieve the desired functionality through a simple circuit design and operational mechanism. As a result, it not only reduces manufacturing costs but also achieves the intended performance. This significantly enhances the practicality of the power controller, making it more versatile in application and more flexible in use.

It will be apparent to those skilled in the art that various modifications and variations can be made to the disclosed embodiments. It is intended that the specification and examples be considered as exemplary only, with a true scope of the present invention being indicated by the following claims and their equivalents.

What is claimed is:

1. A highly compatible power controller, comprising:
a signal identification element comprising a low-frequency signal identifier, wherein the low-frequency signal identifier comprises a comparator, a rising-edge trigger, a falling-edge trigger, a counting unit, and a latch;
a switch driver; and
a switch element;
wherein the comparator is configured to receive a second input signal and to compare the second input signal with a first reference voltage to generate a comparison signal, wherein the rising-edge trigger and the falling-edge trigger are configured to receive the comparison signal, wherein the counting unit comprises a counting element and an OR gate, the OR gate is configured to generate a logic signal according to outputs of the rising-edge trigger and the falling-edge trigger, and the counting element is configured to generate a count output signal according to the logic signal, wherein the latch is configured to determine whether the second input signal is a direct-current signal or a power-frequency signal according to the logic signal and the count output signal so as to control the switch driver to control the switch element.

2. The highly compatible power controller as claimed in claim 1, wherein when the logic signal is at a low-level signal, the counting element is configured to perform counting and generate the count output signal at high level after a count value reaches a count upper limit, and the latch is configured to determine that the second input signal is a direct-current signal according to the logic signal and the count output signal, and generate a direct-current identification signal.

3. The highly compatible power controller as claimed in claim 2, wherein, when the logic signal is at a high-level signal, the counting element is reset and configured to generate the count output signal at low level, and the latch is configured to determine that the second input signal is a power frequency signal according to the logic signal and the count output signal, and generate a power frequency identification signal.

4. The highly compatible power controller as claimed in claim 3, further comprising a reference voltage generator, a current controller, a time controller, a peak current detector, and a zero-crossing detector, wherein the low-frequency signal identifier is connected to the reference voltage generator, wherein the reference voltage generator is connected to the current controller, wherein the current controller is connected to the time controller and the peak current detector, wherein the time controller is connected to the zero-crossing detector, the peak current detector, and the switch driver, wherein the low-frequency signal identifier is configured to receive a second input signal and, upon determining that the second input signal is a direct-current signal, output a direct-current identification signal to the reference voltage generator to generate a reference voltage, wherein the current controller is configured to generate a current control signal according to the reference voltage and a peak current detection signal of the peak current detector, wherein the time controller is configured to generate a first pulse-width modulation signal according to the current control signal, the peak current detection signal, and a zero-crossing detection signal of the zero-crossing detector to control the switch driver to control the switch element.

5. The highly compatible power controller as claimed in claim 4, further comprising an overheat protector connected to the reference voltage generator, wherein the overheat protector transmits an overheat protection signal to the reference voltage generator to reduce the reference voltage when overheat protector detects that a temperature exceeds a temperature threshold.

6. The highly compatible power controller as claimed in claim 4, further comprising an impedance identifier, wherein the low-frequency signal identifier is connected to the impedance identifier, and the impedance identifier is connected to the reference voltage generator, wherein the low-frequency signal identifier is configured to output the power frequency identification signal to the reference voltage generator to generate the reference voltage, wherein the current controller is configured to generate the current control signal according to the reference voltage and the peak current detection signal, wherein the time controller is configured to generate a second pulse-width modulation signal according to the current control signal, the peak current detection signal, and the zero-crossing detection signal to control the switch driver to control the switch element.

7. The highly compatible power controller as claimed in claim 1, further comprising a high-frequency signal identifier, wherein the high-frequency signal identifier is configured to receive a first input signal and execute a counting process within a preset time interval, wherein the counting process comprises a preset number of counting cycles for detecting a number of sine waves in the first input signal, and the high-frequency signal identifier is configured to generate a conduction signal when the number of sine waves in any one of the counting cycles is greater than or equal to a preset threshold, and the switch driver is configured to activate the switch element according to the conduction signal.

8. The highly compatible power controller as claimed in claim 7, wherein the high-frequency signal identifier comprises a counter, a timer, a resetter, and an executor, wherein the resetter is connected to the counter and the timer, and the executor is connected to the counter and the timer, wherein the timer is configured to control the executor to generate an execution signal to control the counter to execute the counting process in order to calculate the number of sine waves in the first input signal, wherein the timer is configured to control a duration of each of the counting cycles, and control the resetter to generate a reset signal when any one of the counting cycles ends so as to reset the counter for next the counting cycle.

9. The highly compatible power controller as claimed in claim 8, wherein the timer is configured to control the resetter to generate a deadlock signal to control the counter to enter a deadlock state when the preset time interval ends.

10. The highly compatible power controller as claimed in claim 1, wherein the switch driver is a gate driver, and the switch element is a metal-oxide-semiconductor field-effect transistor.
